(19) United States
(12) Patent Application Publication
(10) Pub. No.: US 2010/0229061 A1
(43) Pub. Date: Sep. 9, 2010

(54) Cell-Aware Fault Model Creation And Pattern Generation

(76) Inventors: Friedrich HAPKE, Winsen (DE); Rene Krenz-Baath, Hamburg (DE); Andreas Glowatz, Heidenau (DE); Juergen Schloeffel, Buchholz/Sproetze (DE); Peter Weseloh, Rosengarten/Westerhof (DE); Michael Wittke, Pinneberg (DE); Mark A. Kassab, Wilsonville, OR (US); Christopher W. Schuermyer, Happy Valley, OR (US)

Correspondence Address: MENTOR GRAPHICS CORP.;PATENT GROUP, 8005 SW BOECKMAN ROAD, WILSONVILLE, OR, 97070-7777, US

(21) Appl. No.: 12/718,799

(22) Filed: Mar. 5, 2010

Related U.S. Application Data
(60) Provisional application No. 61/157,651, filed on Mar. 5, 2009.

(51) Int. Cl. G01R 31/3177; G06F 11/25

(52) U.S. Cl. 714/740; 714/E11.155

(57) ABSTRACT

Cell-aware fault models directly address layout-based intra-cell defects. They are created by performing analog simulations on the transistor-level netlist of a library cell and then by library view synthesis. The cell-aware fault models may be used to generate cell-aware test patterns, which usually have higher defect coverage than those generated by conventional ATPG techniques. The cell-aware fault models may also be used to improve defect coverage of a set of test patterns generated by conventional ATPG techniques.

### RELATED APPLICATIONS

This application claims priority to U.S. Provisional Patent Application No. 61/157,651, entitled “Defect-Oriented Fault Model Creation And Pattern Generation,” filed on Mar. 5, 2009, and naming Friedrich Hapke et al. as inventors, which application is incorporated entirely herein by reference.

### FIELD OF THE INVENTION

The present invention is directed to testing of integrated circuits (ICs). Various aspects of the invention may be particularly useful for modeling defects and generating high quality test patterns to test ICs for defects that occur during or after the manufacturing process.

### BACKGROUND OF THE INVENTION

A wide range of fault models have been used to generate test patterns for detecting faults in integrated circuits, such as stuck-at, bridging, inter-cell-opens, and transition-faults among others. These fault models share the assumption that faults only occur between library cell instances, at the ports of library cells, and between the interconnect lines outside of library cells. Today's automated test pattern generation (ATPG) tools apply these standard fault models and either assume no faults within library cells, or consider only those faults inside library cells based on the gate models used by the ATPG. These gate models are useful for injecting faults at the cell ports or at the primitive cell structures used by the ATPG, but not suitable for modeling real layout-based defects inside library cells.

Techniques to specifically target cell-internal defects have been proposed. For example, N-detect, embedded-multi-detect (EMD), and gate-exhaustive testing have shown considerable success in detecting (or “covering”) some previously un-modeled defects. However these newly developed techniques may be too complex for real-world designs, or they only improve the likelihood of detecting cell-internal defects in a probabilistic fashion rather than target them in a deterministic fashion. In N-detect testing, the chance of detection is improved by targeting the same fault multiple times under different conditions. This typically increases the number of patterns by a factor of N, however, and therefore makes the test costly. The EMD-based approach increases the number of different defects that can be detected (sometimes referred to as defect “coverage”) by exploiting unused bits in the existing ATPG patterns. Unlike the methods based on N-detect, no additional test patterns are needed with the EMD-based approach. Nevertheless, there exists only a probabilistic relation to actual defects for both techniques. Thus, it is difficult to quantify the additional defect coverage provided by these techniques relative to conventional techniques, and to predict the resulting benefit for future designs. While the gate-exhaustive testing method is able to cover intra-cell defects, the method also tends to generate a very large number of additional patterns and result in high test costs.

### BRIEF SUMMARY OF THE INVENTION

Aspects of the invention relate to cell-aware pattern generation and fault model creation to test ICs for defects that occur during or after the manufacturing process. In various embodiments of the invention, cell-aware fault models are created based on a transistor-level netlist extracted from a library cell's layout view. The cell-aware fault models may be used to generate test cubes and patterns with high defect coverage. According to examples of the invention, test patterns may be generated through a standard ATPG process first. The cell-aware fault models are then applied to embed additional assigned values (e.g., additional test cubes) in the generated test patterns, thereby allowing the defect coverage to be increased without increasing the number of test patterns.

### BRIEF DESCRIPTION OF THE DRAWINGS

FIG. 1 illustrates a programmable computer system with which various embodiments of the invention may be employed.

FIG. 2 illustrates an example of a tool for generating cell-aware fault model and test patterns according to various embodiments of the invention.

FIG. 3 illustrates a process for cell-aware fault model creation in accordance with some embodiments of the present invention.

FIG. 4a illustrates a standard model ATPG example; FIG. 4b illustrates a cell-aware ATPG example.

FIG. 5 illustrates a process for generating cell-aware test cubes in accordance with some embodiments of the present invention.

FIG. 6 illustrates a complete cell-aware ATPG process in accordance with some embodiments of the present invention.

FIG. 7 illustrates an embedded cell-aware ATPG process in accordance with some embodiments of the present invention.

### DETAILED DESCRIPTION OF THE INVENTION

Various aspects of the present invention relate to techniques for generating cell-aware fault models and test patterns to test ICs for defects that occur during or after the manufacturing process. In the following description, numerous details are set forth for purpose of explanation. However, one of ordinary skill in the art will realize that the invention may be practiced without the use of these specific details. In other instances, well-known features have not been described in details to avoid obscuring the present invention.

Some of the techniques described herein can be implemented in software instructions stored on a computer-readable medium, software instructions executed on a computer, or some combination of both. Some of the disclosed techniques, for example, can be implemented as part of an electronic design automation (EDA) tool. Such methods can be executed on a single computer or a networked computer.

Although the operations of the disclosed methods are described in a particular sequential order for convenient presentation, it should be understood that this manner of description encompasses rearrangements, unless a particular ordering is required by specific language set forth below. For example, operations described sequentially may in some cases be rearranged or performed concurrently. Additionally, the detailed description sometimes uses terms like “determine” and “generate” to describe the disclosed methods. Such terms are high-level abstractions of the actual operations that are performed. The actual operations that correspond to these terms will vary depending on the particular implementation and are readily discernible by one of ordinary skill in the art.

### Operating Environment

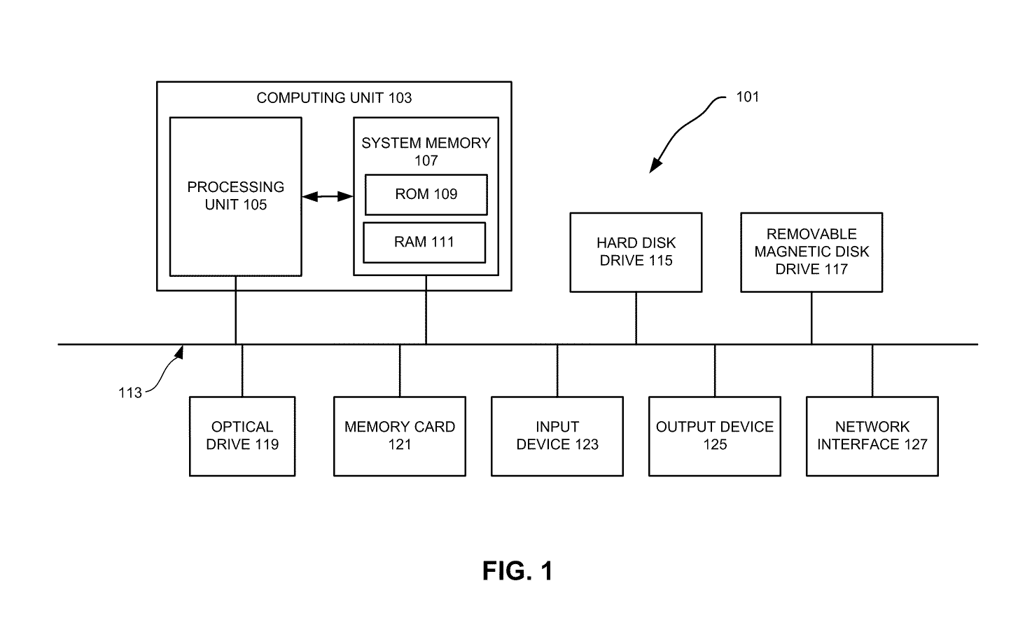

Various embodiments of the invention may be implemented through the execution of software instructions by a computing device, such as a programmable computer. Further, various embodiments of the invention may be implemented by a computer executing various software instructions for performing the functionality of the invention, or by software instructions for performing the functionality of the invention stored on a computer-readable medium. Accordingly, FIG. 1 shows an illustrative example of a computing device 101. As seen in this figure, the computing device 101 includes a computing unit 103 with a processing unit 105 and a system memory 107. The processing unit 105 may be any type of programmable electronic device for executing software instructions, but will conventionally be a microprocessor. The system memory 107 may include both a read-only memory (ROM) 109 and a random access memory (RAM) 111. As will be appreciated by those of ordinary skill in the art, both the read-only memory (ROM) 109 and the random access memory (RAM) 111 may store software instructions for execution by the processing unit 105.

The processing unit 105 and the system memory 107 are connected, either directly or indirectly, through a bus 113 or alternate communication structure, to one or more peripheral devices. For example, the processing unit 105 or the system memory 107 may be directly or indirectly connected to one or more additional memory storage devices, such as a “hard” magnetic disk drive 115, a removable magnetic disk drive 117, an optical disk drive 119, or a flash memory card 121. The processing unit 105 and the system memory 107 also may be directly or indirectly connected to one or more input devices 123 and one or more output devices 125. The input devices 123 may include, for example, a keyboard, a pointing device (such as a mouse, touchpad, stylus, trackball, or joystick), a scanner, a camera, and a microphone. The output devices 125 may include, for example, a monitor display, a printer and speakers. With various examples of the computer 101, one or more of the peripheral devices 115-125 may be internally housed with the computing unit 103. Alternately, one or more of the peripheral devices 115-125 may be external to the housing for the computing unit 103 and connected to the bus 113 through, for example, a Universal Serial Bus (USB) connection.

With some implementations, the computing unit 103 may be directly or indirectly connected to one or more network interfaces 127 for communicating with other devices making up a network. The network interface 127 translates data and control signals from the computing unit 103 into network messages according to one or more communication protocols, such as the transmission control protocol (TCP) and the Internet protocol (IP). Also, the interface 127 may employ any suitable connection agent (or combination of agents) for connecting to a network, including, for example, a wireless transceiver, a modem, or an Ethernet connection. Such network interfaces and protocols are well known in the art, and thus will not be discussed here in more detail.

It should be appreciated that the computer 101 is illustrated as an example only, and it not intended to be limiting. Various embodiments of the invention may be implemented using one or more computing devices that include the components of the computer 101 illustrated in FIG. 1, which include only a subset of the components illustrated in FIG. 1, or which include an alternate combination of components, including components that are not shown in FIG. 1. For example, various embodiments of the invention may be implemented using a multi-processor computer, a plurality of single and/or multiprocessor computers arranged into a network, or some combination of both.

### Cell-Aware Fault Model and Test Pattern Generation Tool

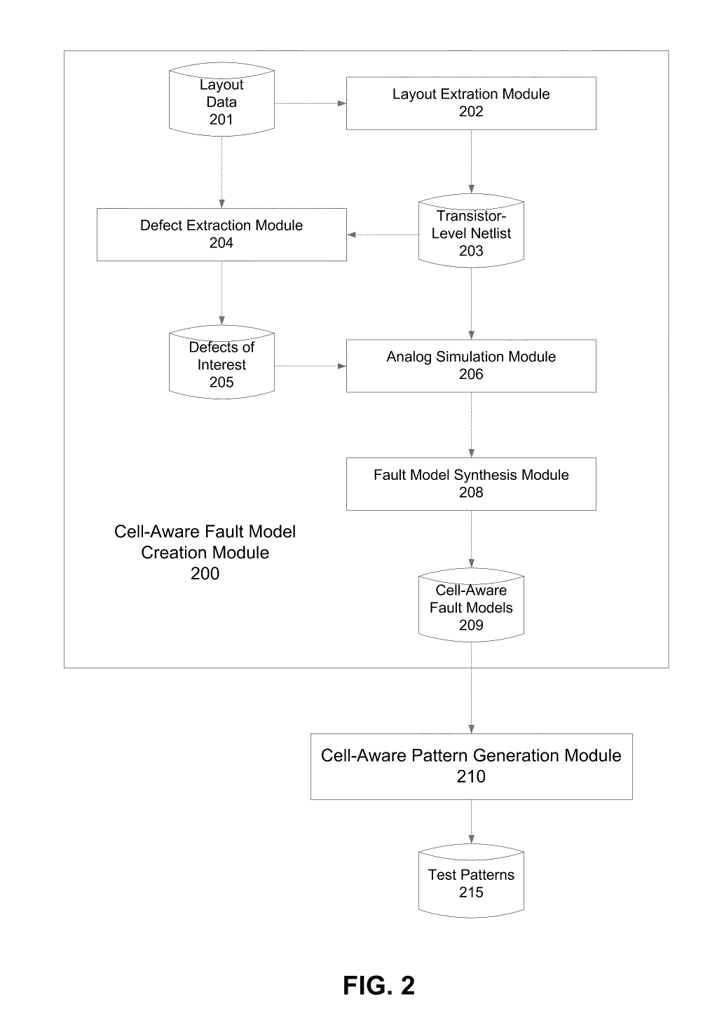

FIG. 2 illustrates an example of a tool for generating cell-aware fault models and test patterns according to various embodiments of the invention. As seen in the figure, the tool has two main modules: a module for cell-aware fault model creation 200 and a module for cell-aware pattern generation 210. The module for cell-aware fault model creation 200 creates fault models for a cell of a library based on the cell's layout data and transistor-level netlist. The module for cell-aware pattern generation 210 then uses the created fault models to generate test patterns with large defect coverage compared to test patterns generated using conventional fault models. The generated cell-aware test patterns may be stored in a database 215.

The module for cell-aware fault model creation 200 may include, as shown in FIG. 2, four sub-modules (a layout extraction module 202, a defect extraction module 204, an analog simulation module 206, and a fault model synthesis module 208) and four data bases (a layout database 201, a transistor-level netlist database 203, a defects of interest database 205, and a cell-aware fault model database 209).

As will be discussed in more detail below, the layout extraction module 202 receives layout data for a cell from the layout data database 201. The layout data may be, for example, in the GDS2 format. The module 202 then performs an extraction process to generate a transistor-level netlist from the layout data. Various conventional techniques can be used to perform the extraction process, such as the CALIBRE® Layout-Versus-Schematic (LVS) tool provided with the CALIBRE® family of physical verification software tool available from Mentor Graphics Corporation of Wilsonville, Oreg. The transistor-level netlist may be stored in the transistor-level netlist database 203 for subsequent operations. The extracted netlist may be, for example, in the SPICE format.

The defect extraction module 204 determines a list of defects of interest for the cell based on the layout data stored in the database 201 and the transistor-level netlist stored in the database 203. Various conventional tools may be used for the extraction process, such as the CALIBRE® xRC™ parasitic extraction tool provided with the CALIBRE® family of physical verification software tool available from Mentor Graphics Corporation of Wilsonville, Oreg. As will be appreciated from the following discussion, the cell-aware fault model creation module 200 can generate fault models and corresponding test patterns for a variety of different defects Accordingly, with various examples of the invention, the defect extraction module 204 can be configured to extract any desired defects that are of interest to a particular user or users. The extracted list of defects of interest may be stored in the defects of interest database 205.

The analog simulation module 206 injects a defect selected from the list of defects stored in the defects of interest database 205 and then performs analog simulation to determine whether the defect is detectable. If it determines that the defect is detectable, the analog simulation module 206 further determines the detection conditions for detecting the defect. The detection conditions may then be used by the fault model synthesis module 208 to generate cell-aware fault models, which are stored in the cell-aware fault models database 209.

As previously noted, various embodiments of the invention may be embodied by a computing system, such as the computing system illustrated in FIG. 1. Accordingly, one or more components of each sub-module of the module for cell-aware fault model creation 200 (modules 202, 204, 206, and 208) and the module for cell-aware pattern generation 210 may be implemented using one or more processors in a computing system. It should be appreciated that, while the layout extraction module 202, the defect extraction module 204, the analog simulation module 206, the fault model synthesis module 208 and the module for cell-aware pattern generation 210 are shown as separate units in FIG. 2, a single computer (or a single process in a computing system) may be used to implement two or more of these modules at different times. Also, various examples of the invention may be embodied by software-executable instructions, stored on a computer-readable medium, for instructing a computing system to implement one or more components of each of the layout extraction module 202, the defect extraction module 204, the analog simulation module 206, the fault model synthesis module 208 and the module for cell-aware pattern generation 210. Further, while the layout data database 201, the transistor-level netlist database 203, the defects of interest database 205, and the cell-aware fault models database 209 are shown as separate units in FIG. 2, a single computer accessible medium may be used to implemented two or more of these databases at different times.

It should be appreciated that, while the module for cell-aware fault model creation 200 includes, in FIG. 2, four sub-modules (a layout extraction module 202, a defect extraction module 204, an analog simulation module 206, and a fault model synthesis module 208), it may includes only a subset of these sub-modules. For example, layout extraction module may be removed if the transistor-level netlists and fault information can be obtained from other sources.

### Cell-Aware Fault Model Creation

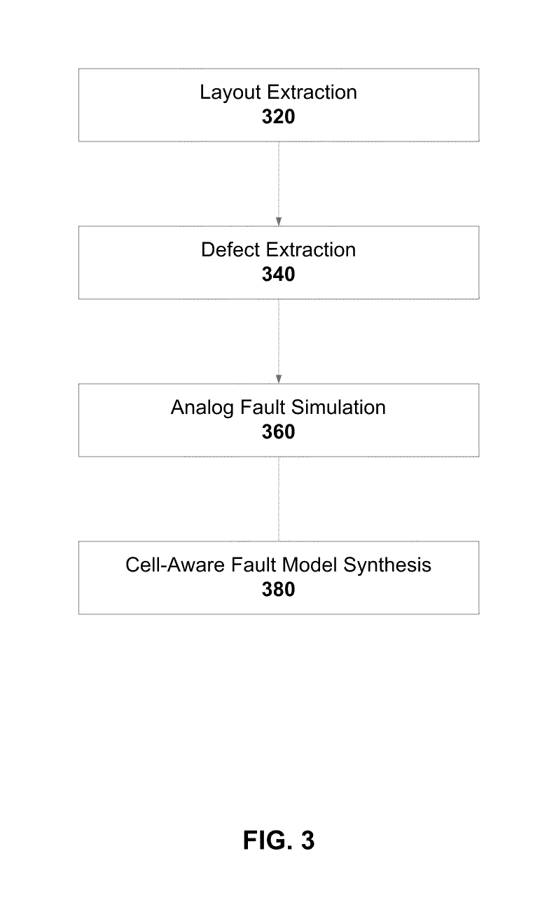

Various methods of fault model creation and test pattern generation according to embodiments of the invention will now be discussed with respect to the flowchart illustrated in FIG. 3. While the operations illustrated in FIG. 3 will be described with reference to the cell-aware fault model and test pattern generation tool shown in FIG. 2, it should be appreciated that the operations illustrated in FIG. 3 may be employed by other implementations of a cell-aware fault model and test pattern generation tool according to various embodiments of the invention. Likewise, it should be appreciated that the cell-aware fault model and test pattern generation tool shown in FIG. 2 may employ techniques for creating fault models or generating test patterns other than the operations shown in FIG. 3.

The flow illustrated in FIG. 3 starts with a layout extraction operation 320, followed by a detection extraction operation 340, then an analog fault simulation operation 360 and finally a synthesis operation 380 to create the cell-aware fault models. Each of these operations will be discussed in more detail below.

In the layout extraction operation 320, the layout extraction module 202 extracts a transistor-level netlist from a layout design (or layout data) of a library cell. As will be appreciated by those of ordinary skill in the art, a layout design represents the features of an electrical circuit using geometric elements. The geometric elements in turn correspond to the physical structures that will be formed on a substrate during a lithographic process to create the circuit. The layout design may be in any desired data format. Data for IC layout descriptions can be provided in many different formats. The Graphic Data System II (GDSII) format is a popular format for transferring and archiving 2D graphical IC layout data. Among other features, it contains a hierarchy of structures, each structure containing layout elements (e.g., polygons, paths or poly-lines, circles and textboxes). The elements are situated on layers. Other formats include an open source format named Open Access, Milkyway by Synopsys, Inc., EDDM by Mentor Graphics, Inc., and the more recent, Open Artwork System Interchange Standard (OASIS) proposed by Semiconductor Equipment and Materials International (SEMI).

As will also be appreciated by those of ordinary skill in the art, the transistor-level netlist is a listing (e.g., a text-based listing) of the significant components of interest in the circuit and their associations. For example, the netlist may list transistors, capacitors, resistors, diodes, and their connections. The netlist may also be in any desired data format, such as, for example, the SPICE data format. With various examples of the invention, the layout extraction module 202 may employ (or, alternately, be implemented by) any suitable electronic design automation (EDA) layout extraction tool can be used to extract the transistor-level netlist from the circuit's layout design. For example, some implementations of the invention may use the Layout-Versus-Schematic (LVS) tool included in the CALIBRE® family of electronic design automation physical verification tools available from Mentor Graphics Corporation of Wilsonville, Oreg. As will be appreciated by those of ordinary skill in the art, by extracting the transistor-level netlist from the layout design, this type of layout extraction tool can correlate geometric elements in the layout design with components in the transistor-level netlist.

In the defect extraction operation 340, the defect extraction module 204 extracts defects of interest from the layout design. Defects of interest could be, for example, bridges between internal nets, bridges to power or ground lines (i.e., Vdd/Vss), missing contacts (i.e., opens), or some combination of different defects. As will be appreciated by those of ordinary skill in the art, there are a variety of electronic design automation tools that may be used by various embodiments of the invention to extract the defects of interest from the layout design. For example, some implementations of the invention may use a parasitic extraction tool, such as one or more of the CALIBRE® xRC™ tools included in the CALIBRE® family of electronic design automation physical verification tools available from Mentor Graphics Corporation of Wilsonville, Oreg. As will be appreciated by those of ordinary skill in the art, a parasitic extraction tool like the CALIBRE® xRC™ tools analyzes the geometric elements in a layout design to identify parasitic features, such as capacitive and inductive features, that would be produced in a circuit manufactured from the layout design.

As will be appreciated by those of ordinary skill in the art, these tools may provide the defects of interest as parasitic features associated with a collection of geometric elements or location data for geometric elements in the layout design. Moreover, because the layout extraction operation 320 produces the transistor-level netlist so that the components in the netlist can be correlated with the geometric elements in the layout design, the netlist also can be correlated with the geometric elements included defects of interest. In this manner, the position of the defects of interest relative to the components in the transistor-level netlist can be determined, and the defects can later be included in the transistor-level netlist.

Next, the analog simulation module 206 performs the analog fault simulation operation 360 on the extracted netlist including the defects of interest. With some embodiments of the invention, the analog simulation module 206 will perform a number of analog simulations for every library cell. The total number of analog simulations that have to be performed, when only one cycle test patterns (non-sequential) are analyzed, may be: n=2^{m}·(d+1), where m and d denote the number of inputs of the library cell and the number of considered defects, respectively, and the operand “+1” correlates to a fault-free simulation. The number of library cell inputs typically is in the range of 1 to 8, while the number of defects could easily be a few hundreds. With today's analog simulators and computer hardware, these simulations can be completed within a few days of run time for a complete cell library. With various implementations of the invention, the analog simulation module 206 may employ (or be implemented using) the ELDO® family of simulation tools available from Mentor Graphics Corporation of Wilsonville, Oreg.

In the case of analog fault simulation of sequential patterns, e.g. to analyze whether an open is detected, robust and non-robust fault simulations may be treated differently. For robust simulations only one cell-input is allowed to change its state from one cycle to another. For non-robust simulations multiple inputs may change their state from one cycle to the next.

For robust sequential tests, the total number of analog simulations for a sequential analysis with 3 cycles (i.e. an initial and a final cycle) is:

N_{2(robust)}=2^{m}·m·(d+1).

For non-robust sequential tests, the total number of analog simulations for a sequential analysis with 3 cycles (i.e. an initial and a final cycle) is:

N_{2(robust)}=2^{m}·(2^{m}−1)·(d+1).

A defect may be inserted by modifying the transistor-level netlist or netlist object values (e.g. resistor values). For example, if a bridge is a defect candidate, then a resistor is inserted between the corresponding two nets. For an open fault, the corresponding electrical object (e.g. transistor gate, resistor, capacitor or the wire) is disconnected (or a very high resistance is included) during the analog simulation.

After a particular defect has been inserted, an exhaustive (or a reduced one in case of robust sequential tests) set of digital input patterns may be simulated on the modified netlist according to some embodiments of the invention. Additionally, each cell may be simulated without defects in order to determine the golden voltage (i.e., the expected voltage) at the cell outputs for every cell-input combination. The simulations are analog DC-analysis simulations which can determine the steady state voltage of the cell output(s). For sequential patterns, a transient analysis is performed.

In accordance with some embodiments of the invention, the analog simulation module 206 may consider a defect detectable if at least for one input combination (or assignment), one or more of the cell's output ports produce a voltage which is inverted to the golden voltage and the produced defective voltage must be in the range of 80%-100% of the supply voltage, or produce a voltage of only 0% to 20% of the golden voltage. Of course, with still other implementations of the invention, the deviation threshold may also be specified by users. The simulations may be automated by a set of scripts around a state-of-the-art analog simulator.

The output of the analog fault simulation operation 340 may be a detection matrix in some embodiments of the invention. The detection matrix' rows and columns refer to input combinations and defects, respectively.

In the cell aware synthesis operation 380, the fault model synthesis module 208 synthesizes cell-aware library views (or cell-aware library models). According to some embodiments of the invention, this synthesis operation will extract a set of necessary input assignments for each fault to relax the future pattern generation process. The following is an example of an algorithm that can be used to implementing the cell aware synthesis operation 380:

```
Generate F from truth table
For each d ε D
  R_{d} = emtpy set;
  g_{d} = OR_{1≦ i ≦ 2}ⁿ tᵢ if tᵢ detectes d, 0 otherwise;
  g_{dF}= AND(g_{d}, F);
  gdF′ = AND(g_{d}, F′);
  R_{d}= R_{d} ∪ derive_prime_cubes(g_{dF′});
  R_{d}= R_{d} ∪ derive_prime_cubes(g_{dF});
End
// Compression stage
P = emtpy set;
M = emtpy set;
For each R_{d}
  For each q ∪ R_{d}
    If ∃ pᵢ ε P pᵢ == q
      M = M ∪ d; // where d = M_{|i|}
    Else
      P= P ∪ q; // where q = P_{|P|}
      M = M ∪ d; // where d = M_{|M|}
    End
  End
End
```

Assuming a detection matrix D is generated for an n-input library cell C implementing the combinational Boolean function F, for every fault d specified in D the algorithm generates a detection function g_{d}( ). This detection function incorporates all fully defined input-assignments which would be required to detect d, i.e. input assignments without don't-cares (or necessary input assignments). As will be appreciated by those of ordinary skill in the art, don't-cares may refer to input ports of a cell or bits in test patterns of which values are irrelevant to detecting defects of interest.

Next, every detection-function is combined with function F and its inverse F′ in order to find the corresponding output assignment for every cube contained in g_{d}( ). After that, all prime cubes of the resulting functions g_{dF}( ) and g_{dF′}( ) are collected in the set R_{d}.

Finally the algorithm compresses identical cubes with respect to all sets R_{d} and the corresponding fault information in two sets P and M, where P denotes the final set of primes cubes (the union of all prime cubes contained in all sets R_{d}, d member of D), and M denotes a set of sets containing every fault d detected by the corresponding prime cube. The mapping between an element of P and a set in M is defined via their indices. This means that the cube Pᵢ detects all faults contained in the set Mᵢ. Note that the described algorithm can be easily extended to handle sequential detection matrices.

### Cell-Aware Pattern Generation

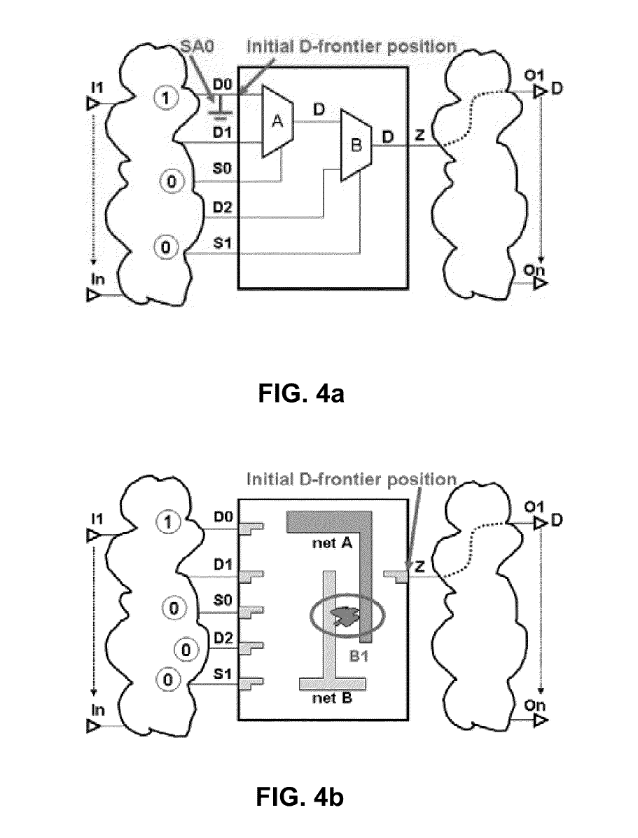

With various implementations of the invention, the cell aware pattern generation module 210 may generate cell-aware patterns based on the cell-aware fault models. In some embodiments of the invention, defects may be injected on a library cell's ports, rather than on inputs or outputs of ATPG primitives. FIG. 4 illustrates the difference with a 3-to-1 multiplexer. The multiplier has three data inputs, two select inputs and one output.

In traditional stuck-at ATPG (SA-ATPG), the fault position (the initial D-frontier position) and the condition for the fault excitation are usually predefined for every ATPG-primitives. In FIG. 4a, an SA0 (Stuck-At 0) fault is at the cell input D0. The SA-ATPG model would define D0=1, S0=0, and S1=0. The other inputs are not required for the detection of the D0 SA0 fault.

By comparison, a cell-aware ATPG (CA-ATPG) process for the same multiplexer is shown in FIG. 4b. Assume there is an intra cell bridge between two nets A and B as indicated in the layout, which serves as a defect. The cell-aware fault model injects this defect at the cell's output port Z. The cell-aware model also applies the necessary conditions to the cell's input ports. Here, one necessary assignment for the fault is D0=1, D2=0, S0=0, and S1=0. Accordingly, the process of fault propagation and justification may be disconnected from the predefined ATPG primitives.

A typical cell-aware fault model usually provides more than one input port assignment for each fault, so there is a set of assignments for an intra-cell defect. A CA-ATPG process can take advantage of it to produce a set of test patterns not only with high defect coverage but also highly compact.

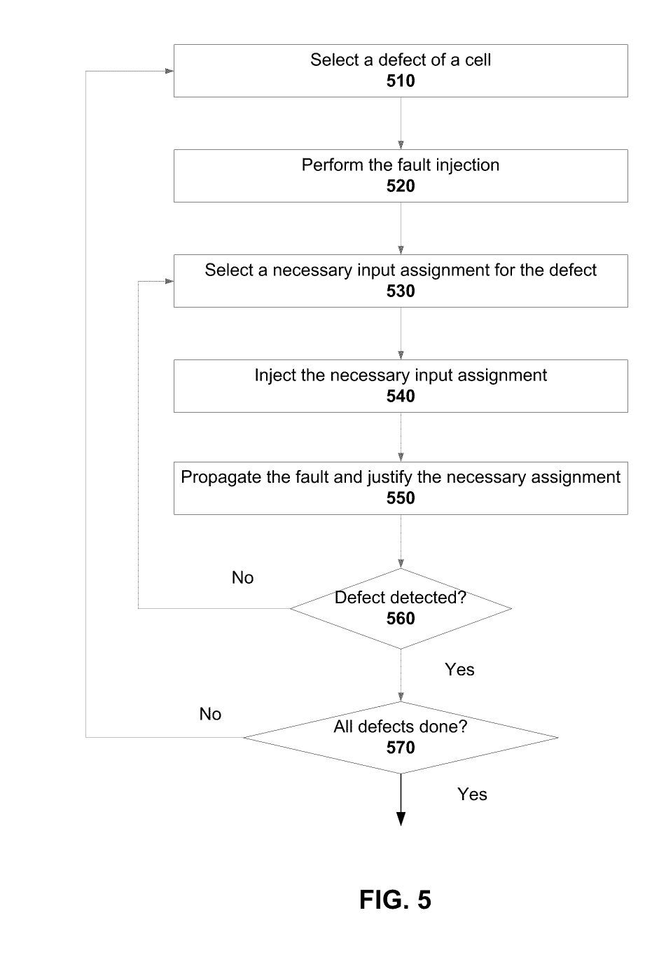

FIG. 5 illustrates a process of generating cell-aware test cubes according to some embodiments of the invention. After injecting a necessary input assignment for a fault at the library cell input ports, and its observation location at one of the library cell output ports, the ATPG algorithm may use state-of-the-art algorithms to propagate the fault to one or more of the outputs of the design and to justify the essential assignments. In case that either the fault propagation or the fault justification fails, another set of optional input assignments is injected for the same fault. This may be repeated until one condition succeeds to propagate the defect effect to at least one output and the input assignments can be justified at the same time. If none of the conditions can be successfully applied, the fault may be declared undetectable and state-of-the-art analysis algorithms can be used to further categorize the reasons for it. Depending on the defect conditions and propagation requirements (as specified in the CA ATPG view) the resulting test pattern can be a single cycle or a multi-cycle test pattern.

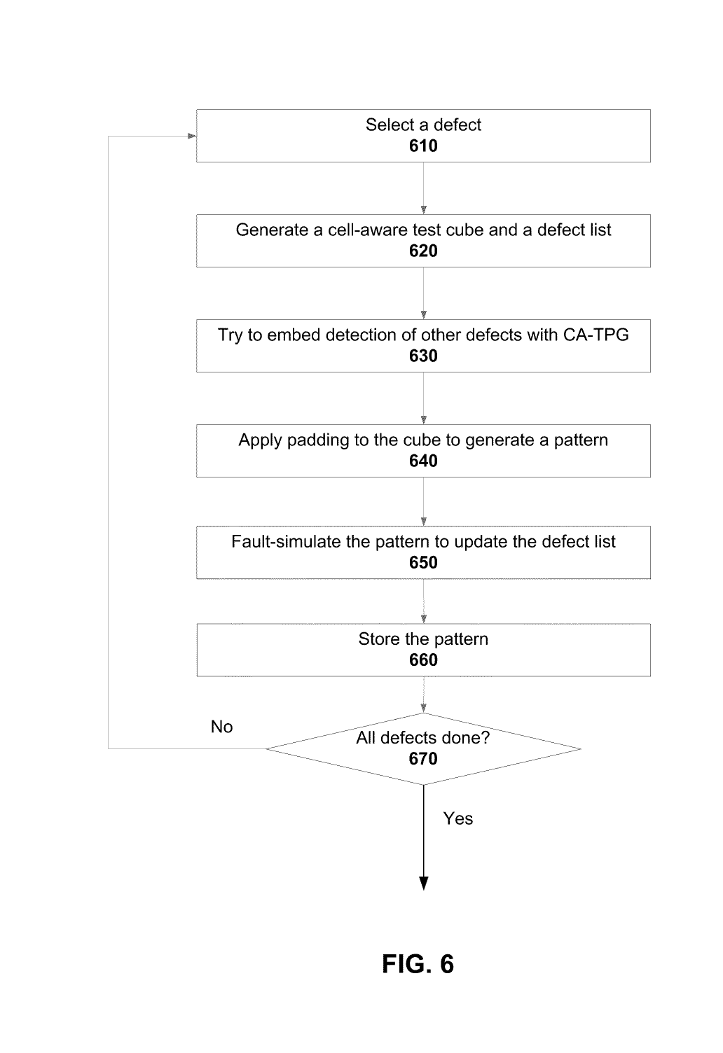

FIG. 6 shows an ATPG process for generating high defect coverage according to some embodiments of the invention. The structure is similar to a conventional ATPG process. However, cell-aware fault models, rather than conventional ones, are applied. In step 610, a defect is selected from a list of potential defects. In step 620, a cell-aware test cube is generated if the defect is detectable. In step 630, the process tries to embed the detection of other defects in the test cube from the list. In step 640, padding is applied to the embedded cube to generate a pattern. In step 650, fault simulation is performed to update the list of defects that can be detected by the pattern. The process repeats the above steps for the rest of the defects.

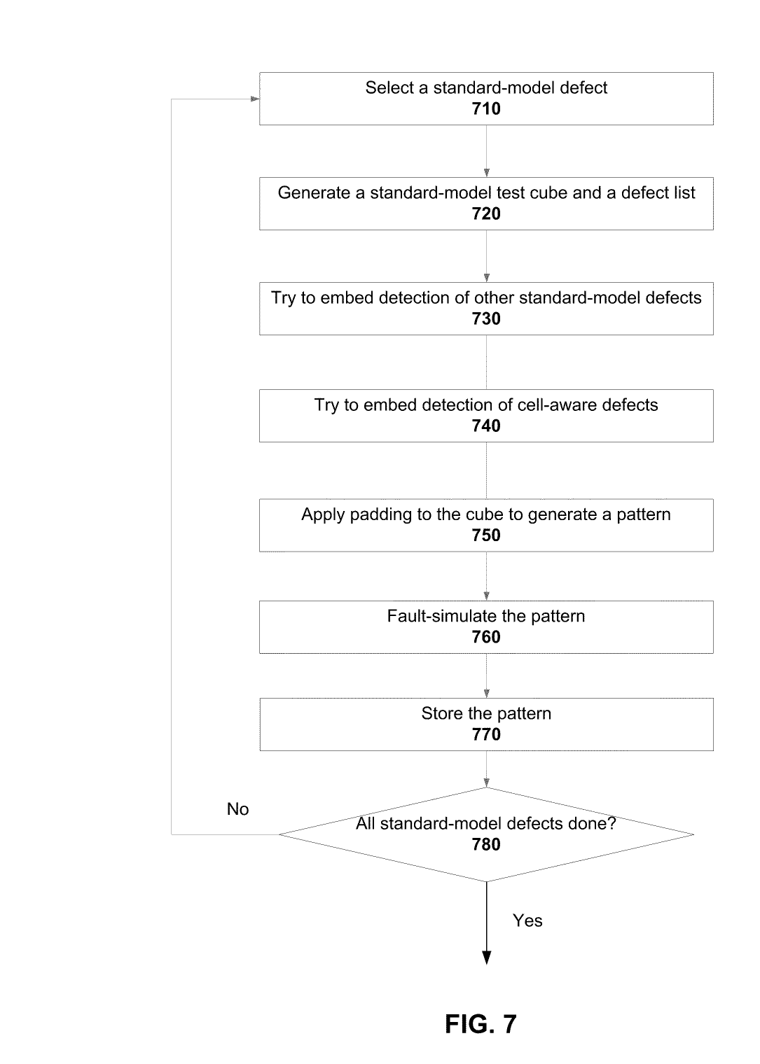

FIG. 7 shows an ATPG process for generating the same amount of patterns as a standard ATPG would generate but with increased defect coverage according to some embodiments of the invention. It is achieved by targeting the cell internal defects only as an additional step after a compact set of patterns has been generated by a conventional ATPG algorithm. In this additional step, the cell-aware fault detections are embedded into the compact set of patterns.

### CONCLUSION

While the invention has been described with respect to specific examples including presently preferred modes of carrying out the invention, those skilled in the art will appreciate that there are numerous variations and permutations of the above described systems and techniques that fall within the spirit and scope of the invention as set forth in the appended claims. For example, while specific terminology has been employed above to refer to electronic design automation processes, it should be appreciated that various examples of the invention may be implemented using any desired combination of electronic design automation processes.

What is claimed is:

1. A method of cell-aware fault model generation comprising:
determining defects of interest for a cell based on layout data of the cell and a transistor-level netlist of the cell;
performing analog fault simulation on the transistor-level netlist to determine detectable defects from the defects of interest and detection conditions for the detectable defects;
generating cell-aware fault models for the detectable defects based on the detection conditions; and
storing the cell-aware fault models in a processor-accessible medium.

2. The method recited in claim 1, wherein the transistor-level netlist of the cell is extracted from the layout data of the cell.

3. The method recited in claim 1, wherein determining defects of interest for a cell comprises:
receiving information with regard to the defects of interest from one or more users; and
determining defects of interest for a cell based on layout data of the cell, a transistor-level netlist of the cell, and the information with regard to the defects of interest received from one or more users.

4. The method recited in claim 1, wherein the detectable defects are defects which after being injected into the transistor-level netlist of the cell individually, cause the cell to produce a voltage satisfying a condition on an output port of the cell for an input combination of the cell.

5. The method recited in claim 1, wherein performing analog fault simulation comprises:
selecting a defect from the defects of interest;
modifying the transistor-level netlist according to the defect to generate a modified transistor-level netlist; and
performing analog simulations on the modified transistor-level netlist to determine whether the defect is detectable and if the defect is detectable, detection conditions for the defect.

6. The method recited in claim 5, wherein performing analog fault simulation further comprises:
determining detection conditions for all of the detectable defects;
generating a detection matrix based on the detection conditions for all of the detectable defects; and
storing the detection matrix.

7. The method recited in claim 1, wherein generating cell-aware fault models comprises:
generating prime cubes by determining necessary input combinations based on the detection information, the necessary input combinations being input combinations required to detect the defects without don't cares; and
combining the prime cubes with corresponding output combinations.

8. The method recited in claim 7, wherein generating cell-aware fault models further comprises:
compressing identical prime cubes to generate a set of compressed prime cubes and a set of defect lists, each defect list denoting defects that can be detected by a compressed prime cube.

9. A method of cell-aware pattern generation, comprising:
selecting a defect for a cell that is used in a circuit;
injecting the defect on one or more of output ports of the cell based on cell-aware fault models associated with the defect;
selecting a necessary input combination from a set of necessary input combinations for the defect provided by the cell-aware fault models;
injecting the necessary input combination on input ports of the cell; and
propagating the defect and justifying the necessary input combination.

10. The method recited in claim 9, further comprising:
denoting the defect is not detectable if the operation of propagating fails or if the operation of justifying fails for each of the set of necessary input combinations.

11. The method recited in claim 9, further comprising:
selecting another necessary input combination from the set of necessary input combinations if the operation of propagating succeeds but the operation of justifying fails;
injecting the another necessary input combination on input ports of the cell;
justifying the another necessary input combination;
repeating the above three operations until one necessary input combination can be justified successfully; and
generating a test cube based on the operation of justifying that is successful.

12. A method of cell-aware pattern generation, comprising:
receiving a set of defects;
generating a test cube for a defect by using cell-aware fault models, the defect being selected from the set of defects;
embedding in the test cube detection of other defects in the set of defects by using the cell-aware fault models to obtain an embedded test cube and a list of defects that can be detected by the embedded test cube;
applying padding to the embedded test cube to generate a test pattern;
fault-simulating the test pattern to update the list of defects; and
storing the test pattern and the list of defects in a tangible processor-accessible medium.

13. A method of cell-aware pattern generation, executed by at least one processor of a computer, comprising:
receiving a set of standard-model defects and a set of cell-aware defects, the set of cell-aware defects being detectable only with cell-aware fault models;
generating a test cube for a standard-model defect by using standard fault models, the standard-model defect being selected from the set of standard-model defects;
embedding in the test cube detection of other standard-model defects in the set of standard-model defects by using the standard fault models to obtain an embedded test cube and a list of standard-model defects that can be detected by the embedded test cube;
embedding in the test cube detection of cell-ware defects in the set of cell-aware defects by using the cell-aware fault models to obtain a further-embedded test cube and a list of cell-aware defects that can be detected by the further-embedded test cube;
compiling a list of defects detectable by the further-embedded test cube by combining the list of standard-model defects with the list of cell-aware defects;
applying padding to the further-embedded test cube to generate a test pattern;
fault-simulating the test pattern to update the list of defects; and
storing the test pattern and the list of defects in a tangible processor-accessible medium.

14. The method recited in claim 13, wherein the standard-model defects include stuck-at defects and the standard fault models include stuck-at fault models.

15. A system for cell-aware fault model generation comprising:
a layout extraction module extracting a transistor-level netlist for a cell from layout data of the cell;
a defect extraction module determining defects of interest based on the layout data and the transistor-level netlist;
an analog simulation module performing analog simulation on the transistor-level netlist to determine detectable defects from the defects of interest and detection conditions for the detectable defects; and
a fault model synthesis module generating cell-aware fault models for the detectable defects based on the detection conditions.

16. A processor-readable medium storing processor-executable instructions for causing one or more processors to perform a method of cell-aware fault model generation, the method comprising:
determining defects of interest for a cell based on layout data of the cell and a transistor-level netlist of the cell;
performing analog fault simulation on the transistor-level netlist to determine detectable defects from the defects of interest and detection conditions for the detectable defects;
generating cell-aware fault models for the detectable defects based on the detection conditions; and
storing the cell-aware fault models in a processor-accessible medium.

17. The processor-readable medium recited in claim 16, wherein the transistor-level netlist of the cell is extracted from the layout data of the cell.

18. The processor-readable medium recited in claim 16, wherein determining defects of interest for a cell comprises:
receiving information with regard to the defects of interest from one or more users; and
determining defects of interest for a cell based on layout data of the cell, a transistor-level netlist of the cell, and the information with regard to the defects of interest received from one or more users.

19. The processor-readable medium recited in claim 16, wherein the detectable defects are defects which after being injected into the transistor-level netlist of the cell individually, cause the cell to produce a voltage satisfying a condition on an output port of the cell for an input combination of the cell.

20. The processor-readable medium recited in claim 16, wherein performing analog fault simulation comprises:
selecting a defect from the defects of interest;
modifying the transistor-level netlist according to the defect to generate a modified transistor-level netlist; and
performing analog simulations on the modified transistor-level netlist to determine whether the defect is detectable and if the defect is detectable, detection conditions for the defect.

21. The processor-readable medium recited in claim 20, wherein performing analog fault simulation further comprises:
determining detection conditions for all of the detectable defects;
generating a detection matrix based on the detection conditions for all of the detectable defects; and
storing the detection matrix.

22. The processor-readable medium recited in claim 16, wherein generating cell-aware fault models comprises:
generating prime cubes by determining necessary input combinations based on the detection information, the necessary input combinations being input combinations required to detect the defects without don't cares; and
combining the prime cubes with corresponding output combinations.

23. The processor-readable medium recited in claim 22, wherein generating cell-aware fault models further comprises:
compressing identical prime cubes to generate a set of compressed prime cubes and a set of defect lists, each defect list denoting defects that can be detected by a compressed prime cube.

24. A processor-readable medium storing processor-executable instructions for causing one or more processors to perform a method of cell-aware pattern generation, the method comprising:
selecting a defect for a cell that is used in a circuit;
injecting the defect on one or more of output ports of the cell based on cell-aware fault models associated with the defect;
selecting a necessary input combination from a set of necessary input combinations for the defect provided by the cell-aware fault models;
injecting the necessary input combination on input ports of the cell; and
propagating the defect and justifying the necessary input combination.

25. The processor-readable medium recited in claim 24, wherein the method further comprises:
denoting the defect is not detectable if the operation of propagating fails or if the operation of justifying fails for each of the set of necessary input combinations.

26. The processor-readable medium recited in claim 24, wherein the method further comprises:
selecting another necessary input combination from the set of necessary input combinations if the operation of propagating succeeds but the operation of justifying fails;
injecting the another necessary input combination on input ports of the cell;
justifying the another necessary input combination;
repeating the above three operations until one necessary input combination can be justified successfully; and
generating a test cube based on the operation of justifying that is successful.

27. A processor-readable medium storing processor-executable instructions for causing one or more processors to perform a method of cell-aware pattern generation, the method comprising:
receiving a set of defects;
generating a test cube for a defect by using cell-aware fault models, the defect being selected from the set of defects;
embedding in the test cube detection of other defects in the set of defects by using the cell-aware fault models to obtain an embedded test cube and a list of defects that can be detected by the embedded test cube;
applying padding to the embedded test cube to generate a test pattern;
fault-simulating the test pattern to update the list of defects; and
storing the test pattern and the list of defects in a tangible processor-accessible medium.

28. A processor-readable medium storing processor-executable instructions for causing one or more processors to perform a method of cell-aware pattern generation, the method comprising:
receiving a set of standard-model defects and a set of cell-aware defects, the set of cell-aware defects being detectable only with cell-aware fault models;
generating a test cube for a standard-model defect by using standard fault models, the standard-model defect being selected from the set of standard-model defects;
embedding in the test cube detection of other standard-model defects in the set of standard-model defects by using the standard fault models to obtain an embedded test cube and a list of standard-model defects that can be detected by the embedded test cube;
embedding in the test cube detection of cell-ware defects in the set of cell-aware defects by using the cell-aware fault models to obtain a further-embedded test cube and a list of cell-aware defects that can be detected by the further-embedded test cube;
compiling a list of defects detectable by the further-embedded test cube by combining the list of standard-model defects with the list of cell-aware defects;
applying padding to the further-embedded test cube to generate a test pattern;
fault-simulating the test pattern to update the list of defects; and
storing the test pattern and the list of defects in a tangible processor-accessible medium.

29. The processor-readable medium recited in claim 28, wherein the standard-model defects include stuck-at defects and the standard fault models include stuck-at fault models.

30. A system comprising one or more processors, the one or more processors programmed to perform a method of cell-aware fault model generation, the method comprising:
determining defects of interest for a cell based on layout data of the cell and a transistor-level netlist of the cell;
performing analog fault simulation on the transistor-level netlist to determine detectable defects from the defects of interest and detection conditions for the detectable defects;
generating cell-aware fault models for the detectable defects based on the detection conditions; and
storing the cell-aware fault models in a processor-accessible medium.

31. The system recited in claim 30, wherein the transistor-level netlist of the cell is extracted from the layout data of the cell.

32. The system recited in claim 30, wherein determining defects of interest for a cell comprises:
receiving information with regard to the defects of interest from one or more users; and
determining defects of interest for a cell based on layout data of the cell, a transistor-level netlist of the cell, and the information with regard to the defects of interest received from one or more users.

33. The system recited in claim 30, wherein the detectable defects are defects which after being injected into the transistor-level netlist of the cell individually, cause the cell to produce a voltage satisfying a condition on an output port of the cell for an input combination of the cell.

34. The system recited in claim 30, wherein performing analog fault simulation comprises:
selecting a defect from the defects of interest;
modifying the transistor-level netlist according to the defect to generate a modified transistor-level netlist; and
performing analog simulations on the modified transistor-level netlist to determine whether the defect is detectable and if the defect is detectable, detection conditions for the defect.

35. The system recited in claim 34, wherein performing analog fault simulation further comprises:
determining detection conditions for all of the detectable defects;
generating a detection matrix based on the detection conditions for all of the detectable defects; and
storing the detection matrix.

36. The system recited in claim 30, wherein generating cell-aware fault models comprises:
generating prime cubes by determining necessary input combinations based on the detection information, the necessary input combinations being input combinations required to detect the defects without don't cares; and
combining the prime cubes with corresponding output combinations.

37. The system recited in claim 36, wherein generating cell-aware fault models further comprises:
compressing identical prime cubes to generate a set of compressed prime cubes and a set of defect lists, each defect list denoting defects that can be detected by a compressed prime cube.

38. A system comprising one or more processors, the one or more processors programmed to perform a method of cell-aware pattern generation, the method comprising:
selecting a defect for a cell that is used in a circuit;
injecting the defect on one or more of output ports of the cell based on cell-aware fault models associated with the defect;
selecting a necessary input combination from a set of necessary input combinations for the defect provided by the cell-aware fault models;
injecting the necessary input combination on input ports of the cell; and
propagating the defect and justifying the necessary input combination.

39. The system recited in claim 38, wherein the method further comprises:
denoting the defect is not detectable if the operation of propagating fails or if the operation of justifying fails for each of the set of necessary input combinations.

40. The system recited in claim 38, wherein the method further comprises:
selecting another necessary input combination from the set of necessary input combinations if the operation of propagating succeeds but the operation of justifying fails;
injecting the another necessary input combination on input ports of the cell;
justifying the another necessary input combination;
repeating the above three operations until one necessary input combination can be justified successfully; and
generating a test cube based on the operation of justifying that is successful.

41. A system comprising one or more processors, the one or more processors programmed to perform a method of cell-aware pattern generation, the method comprising:
receiving a set of defects;
generating a test cube for a defect by using cell-aware fault models, the defect being selected from the set of defects;
embedding in the test cube detection of other defects in the set of defects by using the cell-aware fault models to obtain an embedded test cube and a list of defects that can be detected by the embedded test cube;
applying padding to the embedded test cube to generate a test pattern;
fault-simulating the test pattern to update the list of defects; and
storing the test pattern and the list of defects in a tangible processor-accessible medium.

42. A system comprising one or more processors, the one or more processors programmed to perform a method of cell-aware pattern generation, the method comprising:
receiving a set of standard-model defects and a set of cell-aware defects, the set of cell-aware defects being detectable only with cell-aware fault models;
generating a test cube for a standard-model defect by using standard fault models, the standard-model defect being selected from the set of standard-model defects;
embedding in the test cube detection of other standard-model defects in the set of standard-model defects by using the standard fault models to obtain an embedded test cube and a list of standard-model defects that can be detected by the embedded test cube;
embedding in the test cube detection of cell-ware defects in the set of cell-aware defects by using the cell-aware fault models to obtain a further-embedded test cube and a list of cell-aware defects that can be detected by the further-embedded test cube;
compiling a list of defects detectable by the further-embedded test cube by combining the list of standard-model defects with the list of cell-aware defects;
applying padding to the further-embedded test cube to generate a test pattern;
fault-simulating the test pattern to update the list of defects; and
storing the test pattern and the list of defects in a tangible processor-accessible medium.

43. The system recited in claim 42, wherein the standard-model defects include stuck-at defects and the standard fault models include stuck-at fault models.
